(19) United States
(12) Patent Application Publication
(10) Pub. No.: US 2006/0183300 A1
(43) Pub. Date: Aug. 17, 2006

(54) Porous structures useful as bipolar plates and methods for preparing same

(75) Inventors: Renaut Mosdale, Claix (FR); Sylvie Escribano, Grenoble (FR); Pierre Olry, Relignae (FR)

Correspondence Address: OBLON, SPIVAK, MCCLELLAND, MAIER & NEUSTADT, P.C., 1940 DUKE STREET, ALEXANDRIA, VA, 22314, US

(73) Assignee: COMMISSARIAT A L'ENERGIE ATOMIQUE, Paris 15 eme (FR)

(21) Appl. No.: 10/565,998

(22) PCT Filed: Jul. 28, 2004
(86) PCT No.: PCT/FR04/50362

§ 371 Date: Jan. 27, 2006

(30) Foreign Application Priority Data
Jul. 29, 2003 (FR) 03/50379

(51) Int. Cl. H01L 21/20

(52) U.S. Cl. 438/478

(57) ABSTRACT

The invention relates to a porous structure, characterized in that it comprises a porous matrix (15) made of carbon fabric, said porous matrix being bounded on at least one of its faces (17, 21) by an impermeable layer (19, 23) made of an element chosen from carbon fibres, carbon nanotubes and glassy carbon, said impermeable layer being linked to the porous matrix via carbon-carbon bonds. The invention also relates to a process for manufacturing such porous structures. Application to the fields of fuel cells and heat exchangers.

### TECHNICAL FIELD

The present invention relates to porous structures that can be used in particular as bipolar plates or as an electrode/bipolar plate assembly in fuel cell devices.

The invention also relates to a process for manufacturing such porous structures.

The general field of the invention may be defined as that of fuel cells, in particular fuel cells of the solid-state polymer electrolyte type.

### PRIOR ART

A fuel cell is an assembly generally comprising a plurality of cell elements stacked on top of one another. In each cell element of the fuel cell, an electrochemical reaction is created between two reactants that are introduced continuously into the cell elements. The fuel normally used is hydrogen or methanol, depending on whether this is a cell operating with mixtures of the hydrogen/oxygen type (a cell of the PEMFC type) or a cell operating with mixtures of the methanol/oxygen type (a cell of the DMFC type), respectively.

The fuel is brought into contact with the anode, while the oxidizer, in this case, oxygen, is brought into contact with the cathode.

The cathode and the anode are separated by an electrolyte of the ion-exchange membrane type.

At the anode, the fuel, for example hydrogen, undergoes an oxidation reaction represented by the following equation:
2H₂→4H⁺+4e⁻.

At the cathode, the oxidizer, generally oxygen, undergoes a reduction reaction represented by the following equation:
O₂+4H⁺+4e⁻→2H₂O.

What therefore occurs is an electrochemical reaction whose energy created is converted into electric power. Protons H⁺ flow from the anode towards the cathode, passing through the electrolyte. Electrons produced at the anode are conveyed to the cathode via an external circuit so as to contribute to the production of electric power.

At the same time, at the cathode, water is produced, which is removed from the electrode/membrane/electrode unit.

In the fuel cells of the prior art, several electrode/membrane/electrode units are stacked one on top of another so as to obtain a greater power than that delivered by only one of these units. The electrical junction and electrical continuity between these units generally take place by means of conducting plates, these plates also being called bipolar plates.

It is therefore by means of these bipolar plates that the cathode of one unit can be joined to the anode of an adjacent unit. These bipolar plates furthermore provide the highest possible electrical conductivities so as to avoid the ohmic losses prejudicial to the efficiency of the fuel cell.

The bipolar plates must also fulfil functions other than that of providing electrical junctions.

This is because the anode of a first unit and the cathode of an adjacent second unit must for example be continuously supplied with reactants via these bipolar plates, in which case said plates then play a reactant delivery role.

In addition, the bipolar plates also serve for the extraction of products at the cathode, by incorporation of elements for removing the excess water.

The bipolar plates may furthermore incorporate a heat exchanger serving to counter any overheating within the stack of electrode/membrane/electrode units.

Finally, we note that another function of these bipolar plates may be to provide the electrode/membrane/electrode units with mechanical integrity, especially when they are stacked one on top of another. Such an assembly gives the overall volume of the cell a small thickness, this being very compatible with the intended application such as, for example that in an electric vehicle.

In the prior art, various bipolar plate configurations exist for delivering the reactants.

A first configuration is one in which channels are machined on at least one face of the bipolar plates. These channels are designed to deliver the reactants as uniformly as possible over a surface of the electrode with which they are in contact.

Theses channels are usually organized so that the reactants injected into these channels meander over a large part of the surface of the electrode. The means used to obtain such a result are horizontal sections spaced apart by 180° descending elbows. It should be noted that these sections are also capable of recovering and removing the water produced at the cathode.

However, it has been found that this particular arrangement of means does not provide an exchange area large enough to result in an electrochemical conversion efficiency that is acceptable for an industrial application.

To alleviate this drawback, another configuration has been proposed in the prior art.

In this configuration, a metal foam having a high porosity is used for joining to the metal parts in which machine features are made, this metal foam ensuring that the reactants are properly delivered and the various products are removed.

However, the fact of joining a metal foam with a bipolar plate contributes to the creation of a high resistance, leading to a reduction in electrical conduction within the unit.

Even though the problem associated with electrical conduction can be partly solved by compressing the metal foam, it nevertheless turns out that corrosion problems persist, owing to the highly corrosive chemical nature of the environment of this type of fuel cell, even by using non-corrodible coatings, and especially because of the presence of many defects such as strand breaks within the metal foam.

Thus, the structures used as bipolar plates in the prior art all have one or more of the following drawbacks:

they do not allow effective delivery of the reactants, owing to an insufficient area for exchange between the structure and the element to be supplied with fluid;

they generate, owing to the fact that they may consist of several parts possibly made of different materials, a contact resistance and corrosion problems.

### SUMMARY OF THE INVENTION

The object of the present invention is therefore to propose a porous structure that can be used in particular to form bipolar plates and electrode/bipolar plate assemblies, the said structure remedying the drawbacks of the aforementioned prior art.

The object of the invention is also to provide a process for manufacturing such porous structures.

Thus, according to a first subject, the present invention relates to a porous structure comprising a porous carbon-fibre matrix, said porous matrix being bounded on least one of its faces by an impermeable layer made of a carbon element chosen from carbon fibres, carbon nanotubes, glassy carbon or combinations of these, said impermeable layer being linked to the porous matrix via carbon-carbon bonds.

Such a porous structure has the following advantages:

because it consists only of carbon, this structure possesses electrical continuity, good conductivity and high chemical inertness, which the porous structures of the prior art do not possess;

because the parts of this structure (the matrix and the impermeable layer) are no longer linked by mechanical means but by carbon-carbon bonds, this structure, when it is dedicated to the flow of fluid, will not suffer from any fluid leak problem;

for the same reasons as those mentioned above, when it is dedicated to electrical conduction, the porous structure of the invention will not be subject to a potential drop, in so far as the contact resistance inherent in the structures of the prior art no longer exists, owing to the fact that the various constituent components of the porous structure of the invention are made of the same material (carbon) and are linked together by carbon-carbon bonds; and

finally, the fact of using only carbon elements as explained above for constituting the porous structure makes it possible to reduce the size and weight of the latter.

According to a second object, the present invention relates to a process for manufacturing a porous structure as defined above, the said process comprising a step of producing said impermeable layer(s):

1) by the growth of carbon elements, chosen from carbon fibres and carbon nanotubes, on one face or on two opposed faces of a carbon-fibre matrix followed by densification of said carbon elements; and/or

2) by formation of glassy carbon on one face or on two opposed faces of a carbon-fibre matrix when the carbon element is glassy carbon.

Thus, the process of the invention has the following advantages:

it simplifies the design of the porous regions in so far as, unlike in the processes of the prior art, such porous regions are no longer designed by the superposition of materials of different types;

it allows the porosity of the various constituent parts of the porous region to be controlled;

it makes it possible, thanks to the materials used which are all based on carbon, to obtain a region exhibiting excellent chemical, electrochemical and thermal stability; and

it involves steps that can be carried out in a continuous production line.

Finally, according to a third subject, the present invention relates to a bipolar plate or to an electrode/bipolar plate assembly comprising a porous structure according to the invention.

Other advantages and features of the invention will become apparent in the detailed non-limiting description below.

### BRIEF DESCRIPTION OF THE DRAWINGS

FIGS. 1 to 6 are sectional views of the various porous structures according to the invention.

### DETAILED DESCRIPTION OF PARTICULAR EMBODIMENTS

As mentioned above, the invention relates to porous structures that can be used as a bipolar plate and/or as an electrode/bipolar plate assembly.

Thus, the porous structures consist of a porous carbon-fibre matrix, said porous matrix being bounded on at least one of its faces by an impermeable layer made of an element chosen from carbon fibres, carbon nanotubes and glassy carbon, said impermeable layers being linked to the porous matrix via carbon-carbon bonds.

It should be pointed out that, according to the invention, the porous structure generally has overall an open porosity.

It should be pointed out that the term “porous carbon-fibre matrix” is understood, in the foregoing and in what follows, to mean a flexible component consisting of an entanglement of carbon fibre strands, the degree of entanglement depending on the desired porosity.

The porous matrix is bounded on at least one of its faces by an impermeable layer, that is to say a layer impermeable to gases and liquids. This impermeable layer has the particular feature of being made of a carbon element chosen from carbon fibres, carbon nanotubes and glassy carbon, and of not being joined to the porous matrix by mechanical means but by carbon-carbon bonds.

Consequently, the porous structure constitutes a component that does not have, as is the case with the porous structures of the prior art, a contact resistance responsible, in particular when the porous structures are used as a bipolar plate, for a potential drop.

Depending on the envisaged use of the porous structures of the invention, these may have various configurations.

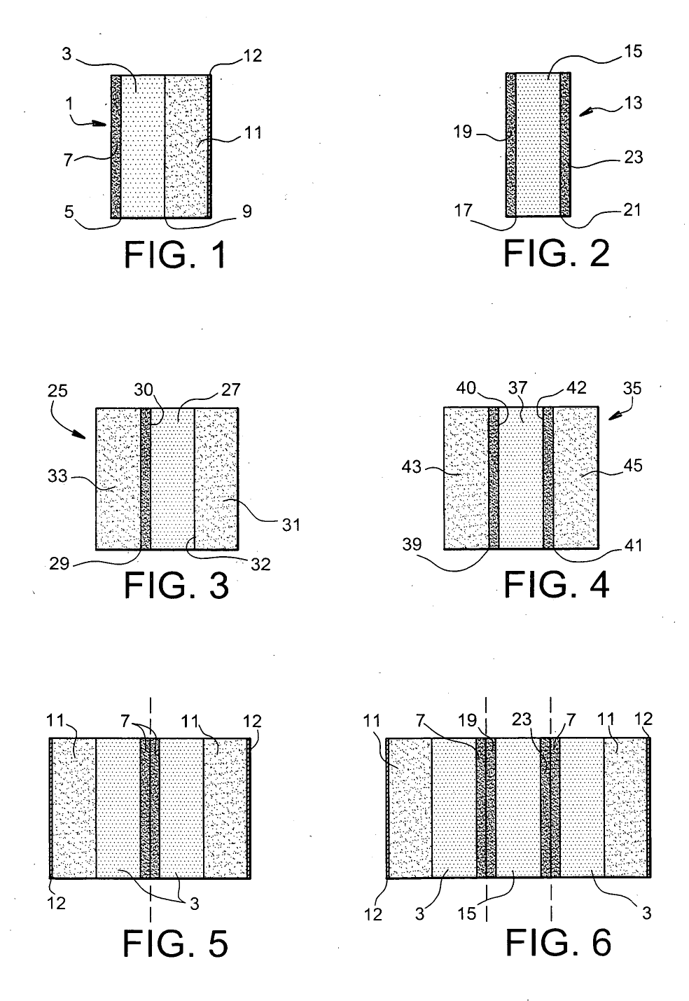

Thus, according to a first embodiment shown in particular in FIG. 1, the porous structure 1 comprises a porous carbon-fibre matrix 3 bounded on a first face 5 by an impermeable layer 7, exhibiting the abovementioned features, and on a second face 9 opposite the first face 5 by a porous layer 11 made of a carbon element chosen from carbon fibres and carbon nanotubes, said porous layer 11 being linked by carbon-carbon bonds to the porous matrix 3. It will be understood that the porous layer will have a predetermined porosity depending on the dedicated use to which this layer is put.

According to a second embodiment shown in FIG. 2, the porous structure 13 comprises a porous matrix 15 bounded on a first face 17 by an impermeable layer 19 and on a second face 21 opposite the first face by another impermeable layer 23, the said impermeable layers 19, 23 being as defined above.

The porous structures of the invention may also include a porous layer, made of a carbon element chosen from carbon fibres and carbon nanotubes, on the abovementioned impermeable layer or layers and/or on a face of the porous matrix, as shown in particular in FIGS. 3 and 4.

Thus, FIG. 3 shows a porous structure 25 comprising a porous matrix 27, bounded on a face 30 by an impermeable layer 29 and on the opposite face 32 by a porous layer 31 as shown in FIG. 1, and also another porous layer 33 on said impermeable layer 29.

FIG. 4 shows a porous structure 35 comprising a porous matrix 37 bounded on two opposed faces 40, 42 by two impermeable layers 39, 41 on either side of said porous matrix 37, to which impermeable layers two porous layers 43, 45 are fixed by carbon-carbon bonds.

It should be noted that, according to any one of the embodiments, the porous structures may include an active layer (with the reference 12 in FIGS. 1, 5 and 6 respectively) deposited on the abovementioned porous layers.

It should be understood that the various simple structures described above may be combined so as to provide more complex structures.

Thus, FIG. 5 corresponds to a complex porous structure resulting from two porous structures 13 as shown in FIG. 1 being joined together via their impermeable layers 7.

FIG. 6 corresponds to a complex porous structure resulting from a porous structure 13 according to FIG. 2 being joined to the two porous structures 1 according to FIG. 1 via their impermeable layers (7, 19, 23).

The porous structures of the invention may be used as a bipolar plate and/or as an electrode/bipolar plate assembly. The porous structures of the invention may also be used in heat exchangers.

It will be recalled that a bipolar plate is a component for physically separating two electrodes of opposite polarity of two adjacent cell elements of a fuel cell, while ensuring electrical continuity. A bipolar plate may fulfil, in addition to its separation roll, the roll of delivering appropriate reactants (namely fuel or oxidizer) to the abovementioned electrodes.

An electrode/bipolar plate assembly is an assembly resulting from the combination of a bipolar plate as defined above and at least one part of an electrode, that is to say the reactant diffusion zone (possibly corresponding to the abovementioned porous layers) and optionally the active region (possibly corresponding to the abovementioned active layer). It should be pointed out that the term “active layer” is understood according to the invention to mean a layer comprising at least one catalyst capable of catalysing the appropriate electrochemical reaction at the electrode in question.

Thus, in particular the porous structures shown in FIGS. 1, 4, 5 and 6 may be used as bipolar plates and/or as an electrode/bipolar plate assembly.

Thus, the structure shown in FIG. 1 may correspond to an electrode/bipolar plate assembly located at the end of a stack when said assembly is intended to be incorporated into a fuel cell consisting of a stack of cell elements. In this case, the impermeable layer 7 and the porous matrix 3 correspond to a half-plate, in so far as it is based only on one electrode, the porous layer 11 corresponds to an electrode reactant diffusion region, and the catalytic layer 12 corresponds to the active region of the electrode.

The structure shown in FIG. 4 may correspond to a bipolar plate that includes a cooling circuit, in which structure:

the porous matrix 37 corresponds to the coolant circulation region;

the porous layers 43, 45 correspond to the reactant delivery regions; and

the impermeable layers 39, 41 separate the coolant circulation region from the reactant delivery regions.

The porous structure shown in FIG. 5 may correspond to an electrode/bipolar plate assembly that does not include a cooling circuit, in which structure:

the porous matrices 3 correspond to the reactant delivery regions;

the porous layers 11 correspond to the diffusion zones for the electrodes belonging to two adjacent cell elements;

the active layers 12 correspond to the active regions of the electrodes belonging to two adjacent cell elements; and

the impermeable layers 7 separate the two reactant delivery regions.

The structure shown in FIG. 6 may correspond to an electrode/bipolar plate assembly that includes a cooling circuit, in which assembly:

the porous matrix 15 corresponds to the coolant circulation region and the porous matrices 3 correspond to two reactant delivery regions;

the porous layers 11 correspond to the diffusion regions for the electrodes belonging to two adjacent cell elements;

the active layers 12 correspond to the active regions of the electrodes belonging to two adjacent cell elements; and

the impermeable layers 7, 19, 23 separate the coolant circulation region from the two reactant delivery regions.

The structure shown FIG. 2 may correspond to a bipolar plate in which:

the porous matrix 15 corresponds to a coolant circulation region; and

the impermeable layers 19 and 23 may provide a separation between two electrodes of two adjacent cell elements of a fuel cell.

Finally, the structure shown in FIG. 3 may correspond to an electrode/bipolar plate assembly with no cooling circuit, in which:

the porous matrix 27 and the porous layer 31 correspond to a reactant delivery region;

the porous layer 33 corresponds to a reactant delivery region different from the abovementioned delivery region; and

the impermeable layer 29 separates the two abovementioned delivery regions.

For the various configurations explained above, it should be understood that the porosity within any one porous layer may vary depending on the use to which this porous layer is put. The porosity between two separate porous layers may also differ depending on whether these porous layers are dedicated to the delivery of a gas (such as O₂) or to the delivery of a liquid (such as methanol).

As mentioned above, the invention relates to a process for manufacturing such a porous structure as defined above, said process including a step of producing said impermeable layer or layers by the growth of carbon elements on one face or on two opposed faces of a carbon-fibre matrix followed by densification of said carbon elements (when these carbon elements are carbon fibres or carbon nanotubes) or by the formation of glassy carbon.

According to the invention, it should be pointed out that the term “carbon-fibre matrix” is understood to mean a component resulting from the entanglement of carbon fibres, the entanglement density varying depending on the desired porosity.

The carbon-fibre matrices may be commercially available or may be produced beforehand, for example by the needle punching of carbon fibres. It should be pointed out that the needle punching technique consists in mechanically entangling the fibres of a fleece in the three directions in space using a needle puncher, it being possible for the entangling operation to be controlled according to the desired porosity.

The step of producing the impermeable layer or layers is carried out in such a way that these impermeable layers are anchored, completely or partly, in the carbon-fibre matrix, more precisely in the constituent pores of this carbon-fibre matrix, via carbon-carbon bonds. What is thus obtained is a porous region (formed by the structure of the carbon-fibre matrix) that is bounded on at least one of its faces by an impermeable layer, which interpenetrates the pores of said matrix, the resulting component thus being a “one-part” component, that is to say a component not resulting form several parts joined together, for example by welding, and not having the drawbacks inherent in this type of component, as was mentioned above.

Thus, such an impermeable layer may be obtained by the growth of carbon elements on at least one of the faces of a carbon-fibre matrix followed by densification of said carbon elements, when the carbon elements are carbon fibres or carbon nanotubes. Such an impermeable layer may also be obtained by the formation of glassy carbon on at least one of the faces of a carbon-fibre matrix. It is also conceivable to combine both the growth of carbon elements and the formation of glassy carbon, when the impermeable layer comprises both carbon elements, such as carbon fibres or carbon nanotubes, and glassy carbon.

When the carbon elements are carbon fibres, the step of growing said carbon fibres may consist in pyrolizing carbon fibre precursor fibres, said precursor fibres possibly being polymer fibres such as polyacrylonitrile (PAN) fibres or fibres obtained from pitch, the pyrolysis step being preceded by the following steps:

a step of impregnating the appropriate face of the carbon-fibre matrix with appropriate monomers or with petroleum pitch;

if the precursor fibres are polymer fibres, a step of polymerizing said monomers followed by a spinning operation in order to obtain the appropriate polymer fibres; or

if the precursor fibres are pitch fibres, a spinning step so as to obtain pitch fibres.

It will be understood that the spinning operation is carried out so as to obtain a network of fibres that are sufficiently entangled so that, at the end of the pyrolysis, the resulting layer is an impermeable layer.

The step of growing carbon nanotubes may be carried out on the carbon-fibre matrix using a process as defined in FR 2 844 510. This process comprises in particular the following steps:

a step of impregnating the appropriate face of the matrix with an aqueous solution containing one or more salts of metal catalyst for the growth of nanotubes, such as Co, Ni or Fe salts in the form of nitrates or acetates;

a step of decomposing said salt(s) into oxide(s) by heat treatment, for example by heating the impregnated matrix to a temperature between 100° C. and 250° C.;

a step of reducing the oxide(s) formed, for example by putting the matrix into a furnace operating in a reducing atmosphere; and

a step of synthesizing the carbon nanotubes by bringing the matrix into contact with a gaseous carbon precursor in a furnace heated to a temperature allowing the formation of carbon by decomposition (cracking) of the gaseous precursor.

The gaseous precursor may be an aromatic or non-aromatic hydrocarbon. For example, acetylene, ethylene, propylene or methane may be used. The furnace temperature required for cracking may range from 450° C. to 1200° C.

The structure obtained (whether the impermeable layer is made of carbon fibres or carbon nanotubes) is then densified by liquid processing or by chemical vapour infiltration, as described in document FR 2 844 510.

The glassy carbon formation step may be carried out by impregnating the carbon-fibre matrix on the appropriate face with a furan resin or a phenolic resin, followed by a pyrolysis step.

When the porous structure of the invention comprises one or more matrix-bounding porous layers that are made of fabric or are deposited on the impermeable layers, said porous layer(s) may be obtained by the growth of carbon elements such as carbon fibres and carbon nanotubes, the growth being controlled so as to obtain, after this growth operation, a layer having the desired porosity.

When the porous structure also includes a catalyst-based active layer, the latter may be obtained by techniques conventionally employed in the manufacture of active layers, such as by coating or spraying suspensions containing the appropriate catalyst. Such suspensions may be a suspension of platinized carbon.

Thus, owing to their characteristics mentioned above, the porous structures of the invention, thanks to the presence of various regions of defined porosity, are applicable not only in the field of fuel cells, of the PEMFC or DMFC type operating at low temperature and cells operating at intermediate temperature (such as phosphoric acid cells operating at 250° C.) as bipolar plates, but also in the field of heat exchangers.

1-8. (canceled)

9. A porous structure comprising a porous carbon-fibre matrix, said porous matrix being bounded on least one of its faces by an impermeable layer comprising a carbon element selected from the group consisting of carbon fibres, carbon nanotubes, glassy carbon and mixtures thereof, said impermeable layer being linked to the porous matrix via carbon-carbon bonds.

10. The porous structure according to claim 1, in which said porous matrix is bounded on a first face by an impermeable layer, as defined in claim 1, and on a second face opposite the first face by a porous layer comprising a carbon element selected from the group consisting of carbon fibres, carbon nanotubes and mixtures thereof, said porous layer being linked via carbon-carbon bonds to the porous matrix.

11. The porous structure according to claim 1, in which said porous matrix is bounded on a first face by an impermeable layer and on a second face opposite the first face by another impermeable layer, said impermeable layers being as defined in claim 1.

12. The porous structure according to claim 1, which further comprises a porous layer comprising a carbon element selected from the group consisting of carbon fibres, carbon nanotubes and mixtures thereof, on said impermeable layer or layers and/or on one face of the porous matrix.

13. The porous structure according to claim 2, wherein the porous structure further comprises an active layer on said porous layer or layers.

14. A bipolar plate or electrode/bipolar plate assembly comprising a porous structure as defined in claim 1.

15. A process for manufacturing a porous structure as defined in claim 1, comprising:
1) growing carbon elements, selected from the group consisting of carbon fibres, carbon nanotubes and mixtures thereof, on one face or on two opposed faces of a carbon-fibre matrix followed by densification of said carbon elements; and/or
2) forming glassy carbon on one face or on two opposed faces of a carbon-fibre matrix when the carbon element is glassy carbon.

16. A process for manufacturing a porous structure according to claim 7, comprising producing said carbon-fibre matrix by the needle-punching of carbon fibres.
